(19) United States
(12) Patent Application Publication
(10) Pub. No.: US 2009/0014729 A1
(43) Pub. Date: Jan. 15, 2009

(54) Semiconductor light emitting device including group III nitride semiconductor

(75) Inventors: Satoshi Nakagawa, Kyoto-fu (JP); Hiroki Tsujimura, Kyoto-fu (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/216,750

(22) Filed: Jul. 10, 2008

(30) Foreign Application Priority Data
Jul. 11, 2007 (JP) P2007-182215

(51) Int. Cl. H01L 33/00

(52) U.S. Cl. 257/76; 257/98; 257/E33.025; 257/E33.067

(57) ABSTRACT

A semiconductor light emitting device comprises: a substrate; a semiconductor stack formed on one of surfaces of the substrate, the semiconductor stack including an active layer composed of a group III nitride semiconductor having a substantially nonpolar or substantially semipolar plane as a main surface; a first electrode formed in a part of a first electrode surface which is the other surface of the substrate; and a second electrode formed on a second electrode surface opposite to the first electrode surface across the substrate and semiconductor stack.

### CROSS REFERENCE TO RELATED APPLICATION AND INCORPORATION BY REFERENCE

This application is based upon and claims the benefit of priority from prior Japanese Patent Application P2007-182215 filed on Jul. 11, 2007; the entire contents of which are incorporated by reference herein.

### BACKGROUND OF THE INVENTION

1. Field of the Invention

The present invention relates to a semiconductor light emitting device including an active layer composed of a group III nitride semiconductor.

2. Description of the Related Art

A semiconductor light emitting device including an active layer composed of a group III nitride semiconductor has been known. Patent Literature 1 (Japanese Patent No. 3412563) discloses a semiconductor light emitting device which includes a sapphire substrate; a semiconductor stack which is composed of a GaN-based semiconductor including an n-type semiconductor layer, an active layer, and a p-type semiconductor layer and is formed on one of surfaces (hereinafter, a front surface) of the substrate; a cathode electrode formed on the n-type semiconductor layer; an anode electrode formed on the p-type semiconductor layer; and a reflection layer formed on the other surface (hereinafter, a rear surface) of the substrate. In the semiconductor light emitting device of Patent Literature 1, the cathode and anode electrodes are formed on the same side as described above.

In this semiconductor light emitting device, when forward voltage is applied between the cathode and anode electrodes, electrons are injected from the cathode electrode into the semiconductor stack, and holes are injected from the anode electrode into the semiconductor stack. The injected electrons and holes are recombined at the active layer to emit light. Part of the emitted light travels towards the electrodes and then projected to the outside. While part of the emitted light which travels towards the substrate is reflected by the reflection layer to the electrodes side and then projected to the outside.

However, in the semiconductor light emitting device described in the aforementioned Patent Literature 1, light emitted at the active layer is not polarized. Moreover, light is extracted through the surface on the side of the cathode and anode electrodes. Accordingly, light is blocked by the two electrodes, wires bonded to the electrodes, and the like, or a certain percentage of light is absorbed even if the anode electrode is a transparent electrode, thus causing a problem of low light extraction efficiency.

### SUMMARY OF THE INVENTION

The present invention was invented to solve the aforementioned problem, and an object of the present invention is to provide a semiconductor light emitting device with a polarization ratio of light from the active layer increased and a light extraction efficiency increased.

A semiconductor light emitting device includes: a substrate; a semiconductor stack formed on one of surfaces of the substrate and including an active layer composed of a group III nitride semiconductor having a main surface which is a substantially nonpolar plane or substantially semipolar plane;

a first electrode formed in a part of a first electrode surface which is the other surface of the substrate; and

a second electrode formed on a second electrode surface opposite to the first electrode surface across the substrate and semiconductor stack.

Herein, the above substantially nonpolar plane is a nonpolar plane and a plane with an off angle of ±1° or less from a nonpolar plane. The above substantially semipolar plane is a semipolar plane and a plane with an off angle of ±1° or less from a semipolar plane and except for a polar plane.

According to the semiconductor light emitting device of the present invention, the active layer whose main surface is the substantially nonpolar or substantially semipolar plane, so that polarized light can be emitted at the active layer. Moreover, the first and second electrodes are formed on opposite sides with the substrate and semiconductor stack interposed therebetween, and the first electrode is formed in a part of the first electrode surface, so that light can be extracted from the part of the first electrode surface where the first electrode is not formed. This can increase the light extraction efficiency and can prevent the reduction in polarization ratio due to dispersion at the interface between each electrode and substrate. It is therefore possible to increase the polarization ratio and increase the light extraction efficiency.

### BRIEF DESCRIPTION OF DRAWINGS

FIG. 1 is a cross-sectional view of a semiconductor light emitting device according to a first embodiment.

FIG. 2 is a bottom view of the semiconductor light emitting device in a direction of an arrow II.

FIG. 3A is a view for explaining an atom arrangement of a unit cell of a hexagonal crystal structure.

FIG. 3B is a view for explaining a nonpolar plane of the hexagonal crystal.

FIG. 3C is a view for explaining a semipolar plane of the hexagonal crystal.

FIG. 4 is a cross-sectional view of an active layer.

FIG. 5 is a cross-sectional view of a semiconductor light emitting device according to a second embodiment.

FIG. 6 is a cross-sectional view of the semiconductor light emitting device according to the second embodiment at a manufacturing step.

FIG. 7 is a cross-sectional view of the semiconductor light emitting device according to the second embodiment at another manufacturing step.

FIG. 8 is a cross-sectional view of the semiconductor light emitting device according to the second embodiment at still another manufacturing step.

FIG. 9 is a cross-sectional view of a semiconductor light emitting device according to a third embodiment.

FIG. 10 is a cross-sectional view of a reflection layer.

### DETAILED DESCRIPTION OF THE INVENTION

### First Embodiment

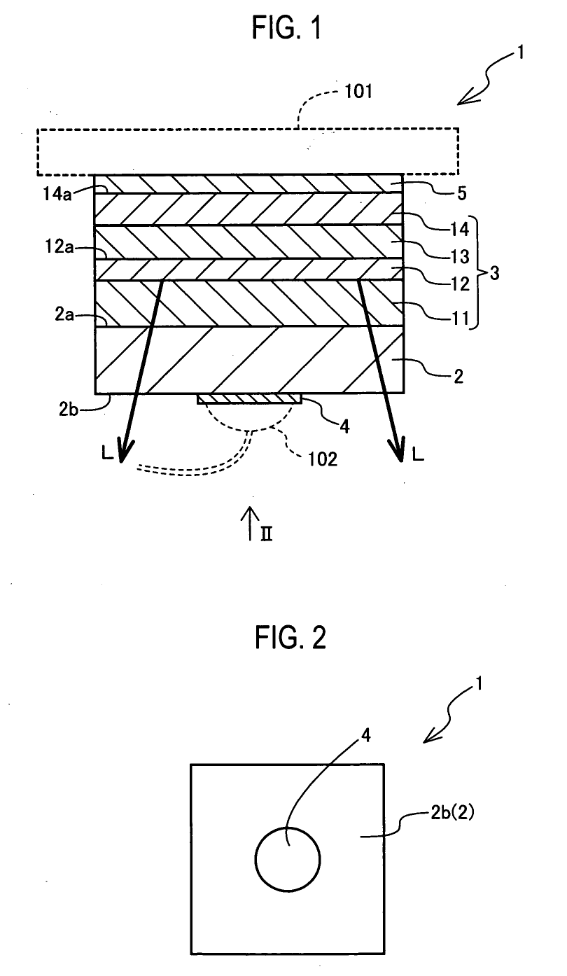

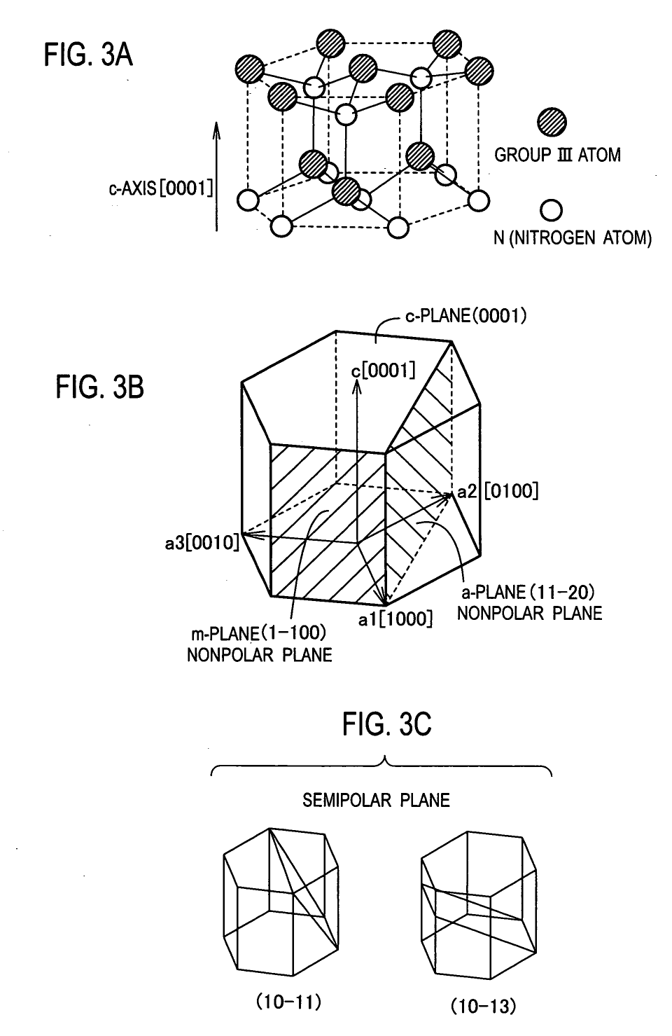

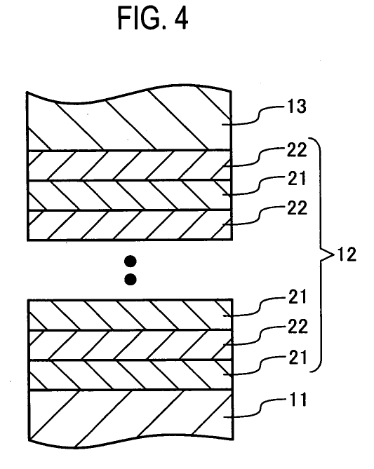

Hereinafter, a description is given of a first embodiment of the present invention with reference to the drawings. FIG. 1 is a cross-sectional view of a semiconductor light emitting device according to the first embodiment. FIG. 2 is a bottom view of the semiconductor light emitting device in a direction of an arrow II. FIGS. 3A to 3C are views for explaining a unit cell having a hexagonal crystal structure. FIG. 4 is a cross-sectional view of an active layer.

As shown in FIGS. 1 and 2, a semiconductor light emitting device 1 according to the first embodiment includes a substrate 2, a semiconductor stack 3, a cathode electrode (corresponding to a first electrode of claims) 4, and an anode electrode (corresponding to a second electrode of claims) 5.

The substrate 2 is composed of conductive n-type GaN which has a hexagonal crystal structure and is doped with silicon as an n-type dopant. The substrate 2 has a thickness of about 100 to 300 μm. A surface (hereinafter, referred to as a main surface) 2a of the substrate 2 is a surface on which the semiconductor stack 3 is epitaxially grown. The main surface 2a of the substrate 2 is composed of an m-plane which is nonpolar.

Herein, a description is given of the hexagonal crystal structure of group III nitride semiconductors such as GaN with reference to the drawings.

As shown in FIG. 3A, in a group III nitride semiconductor having a hexagonal crystal structure, a single group III atom is combined with four nitrogen atoms. The four nitrogen atoms are located at four vertexes of a regular tetrahedron with the group III atom located at the center. As for these four nitrogen atoms, one nitrogen atom is located in the +c axis direction with respect to the group III atom, and the other three nitrogen atoms are located in the −c axis side with respect to the group III atom. The hexagonal group III nitride semiconductor therefore has polarization along the c-axis direction.

As shown in FIG. 3B, the c axis extends along the central axis of a hexagonal cylinder, and surfaces whose normal lines are corresponds to the c-axis (top surfaces of the hexagonal cylinder) are c-plane (0001). When a crystal of a group III nitride semiconductor is cleaved at two planes in parallel to the c-plane, +c plane is a crystal face with group III atoms arranged, and −c plane is a crystal face with nitrogen atoms arranged. Accordingly, the +c plane and −c plane are polar planes having different characteristics.

Side surfaces of the hexagonal cylinder are m-plane (1-100), and planes passing pairs of ridge lines not adjacent to each other are a-plane (11-20). These are crystal faces orthogonal to c-plane and orthogonal to the polarization direction. Accordingly, these planes have not polarization, or are nonpolar. Furthermore, as shown in FIG. 3C, crystal faces which are tilted to c-plane (not in parallel and orthogonal thereto) are diagonal to the polarization direction and therefore planes with some polarization, or a semipolar plane. Specific examples of the semipolar plane are plane (10-11), plane (10-13), and plane (11-22).

The other surface (hereinafter, referred to as a rear surface) 2b of the substrate 2 is a surface through which light is extracted from the later-described active layer 12. The rear surface 2b of the substrate 2 is corresponding to a first electrode surface of claims. The rear surface 2b of the substrate 2 is mirror-finished by chemical mechanical polishing (CMP) in order to suppress reduction of the polarization ratio of polarized light L emitted by the active layer 12 so that the surface roughness is not more than wavelength of the light L emitted at the active layer 12, or preferably, not more than “wavelength/refraction index of the substrate 2”. For example, the roughness of the surface of the substrate 2 is made not more than about 100 nm.

The semiconductor stack 3 is formed by epitaxially growing a group III nitride semiconductor having a hexagonal crystal structure on the main surface 2a of the substrate 2. The semiconductor stack 3 includes an n-type contact layer 11, an active layer 12, a p-type electron blocking layer 13, and p-type contact layer 14 which are sequentially stacked from the substrate 2 side.

The n-type contact layer 11 is composed of an n-type GaN layer which is doped with silicon having a concentration of about 1×10¹⁸ cm⁻³ as an n-type dopant and has a thickness of not less than about 3 μm.

The active layer 12 emits about 430 to 485 nm blue light. As shown in FIG. 4, the active layer 12 has a multiple quantum well structure including 5 to 11 pairs of well layers 21 and barrier layers 22 alternately formed. Each of the well layers 21 is composed of an about 3 nm thick InₓGa₁₋ₓN layer (0.05<=X<=0.2) doped with silicon. Each of the barrier layers 22 is composed of an about 9 nm thick non-doped GaN layer.

The p-type electron blocking layer 13 prevents electrons injected from the n-type contact layer 11 to the active layer 12 from flowing to reach the p-type contact layer 14. The p-type electron blocking layer 13 is composed of an about 28 nm thick p-type AlGaN layer doped with magnesium having a concentration of about 3×10¹⁹ cm⁻³ as a p-type dopant.

The p-type contact layer 14 is composed of an about 70 nm thick p-type GaN layer doped with magnesium having a concentration of about 1×10²⁰ cm⁻³ as a p-type dopant.

As described above, each of the layers 11 to 14 constituting the semiconductor stack 3 is composed of the group III nitride semiconductor of the hexagonal crystal structure which is epitaxially grown on the main surface 2a of the substrate 2 composed of m-plane. Accordingly, similar to the main surface 2a of the substrate 2, each of a main surface 12a of the active layer 12 and main surfaces of the layers 11, 13, and 14 are composed of non-polar m-plane.

The cathode electrode 4 is a part of the rear surface 2b of the substrate 2 and is formed in central part including the center thereof. The cathode electrode 4 is ohmically connected to the rear surface 2b of the substrate 2. The cathode electrode 4 is composed of a metallic layer including an about 10 nm thick Ti layer and an about 100 nm thick Al layer sequentially stacked from the substrate 2 side. Herein, in the light of extraction of light through the rear surface 2b of the substrate 2, it is preferable that the cathode electrode 4 should be small. However, in the light of bonding of the wire 102 connected to the printed circuit board 101, it is preferable that the cathode electrode 4 should be large. Accordingly, the plane area of the cathode electrode 4 is not more than 50% of the plane area of the rear surface 2b of the substrate 2 and preferably about 7 to 8%.

The anode electrode 5 is formed on the entire surface of an upper surface (corresponding to a second electrode surface of claims) 14a of the p-type contact layer 14. The anode electrode 5 is ohmically connected to the p-type contact layer 14. The anode electrode 5 has a thickness of about 200 nm to 300 nm and is composed of ZnO capable of transmitting light.

Next, a description is given of an operation of the aforementioned semiconductor light emitting device 1.

When forward voltage is applied to the semiconductor light emitting device 1, electrons are injected from the cathode electrode 4 into the substrate 2 while holes are injected from the anode electrode 5 to the semiconductor stack 3. The injected electrons are injected into the active layer 12 through the substrate 2 and n-type contact layer 11. Herein, since the cathode electrode 4 is formed in the central part of the rear surface 2b of the substrate 2, the electrons can be injected substantially uniformly in the horizontal direction (perpendicular to the stacking direction). The injected holes are injected into the active layer 12 through the p-type contact layer 14 and p-type electron blocking layer 13. Herein, since the anode electrode 5 is formed so as to cover the entire surface of the p-type contact layer 14, holes are injected into the entire area in the horizontal direction. The electrons and holes injected into the active layer are recombined in the well layer 21 and emit the blue light L. Herein, since the main surface 2a of the active layer 12 is composed of nonpolar m-plane, the light L emitted at the well layer 23 can be polarized in the a-axis direction. The polarized light travels in a direction perpendicular to the polarization direction. Accordingly, most of the light L emitted at the active layer 12 travels in the m-axis direction (stacking direction) and c-axis direction. Specifically, the polarized light L traveling in the m-axis direction and c-axis direction is about several times to 10 times more than light traveling in the a-axis direction.

Among the light L emitted at the active layer 12, the light L traveling toward the substrate 2 is transmitted through the n-type contact layer 11 and substrate 2 and projected to the outside through an area of the rear surface 2b of the substrate 2 where the cathode electrode 4 is not formed. Herein, since the rear surface 2b of the substrate 2 is mirror-finished, the reduction of the polarization ratio of the polarized light L is suppressed. Among the light L emitted at the active layer 12, the light traveling towards the anode electrode 5 is transmitted through the anode electrode 5 and projected to the outside.

Next, a description is given of a method for manufacturing the aforementioned semiconductor light emitting device 1.

First, the substrate 2 which is composed of GaN single crystal and whose main surface 2a is non-polar m-plane is prepared. Herein, the substrate 2 including the main surface 2a of m-plane is produced by first cutting GaN single crystal whose main surface is c-plane and then polishing the same by CMP so that orientation errors with respect to both the directions (0001) and (11-20) are within ±1 degree (preferably within ±0.3 degrees). This makes it possible to obtain the substrate 2 whose main surface 2a is m-plane and which has surface roughness reduced to an atomic level. Moreover, the substrate 2 includes few crystal faults such as dislocation and stacking faults. Moreover, after the main surface 2a is polished, the rear surface 2b of the substrate 2 is polished by CMP for mirror finishing so that the surface roughness is not more than about 100 nm.

Next, the semiconductor stack 3 is epitaxially grown on the aforementioned main surface 2a of the substrate 2 by MOCVD. Specifically, the substrate 2 is introduced into a processing chamber of a MOCVD machine (not shown) and arranged on a susceptor capable of heating and rotating. The atmosphere in the processing chamber is exhausted so that the inside thereof is 1/10 atm to ordinary pressure.

Next, to reduce the roughness of the main surface 2a of the substrate 2, the temperature of the substrate is increased to about 1000° C. to 1100° C. while ammonium gas is supplied into the processing chamber with carrier gas (H₂ gas).

Next, ammonium gas, trimethylgallium (hereinafter, TMG) gas, and silane are supplied to the processing chamber with carrier gas to epitaxially grow the n-type contact layer 11 composed of the n-type GaN layer doped with silicon on the main surface 2a of the substrate 2.

Next, after the temperature of the substrate 2 is set to about 700° C. to 800° C., the active layer 12 is formed on the n-type contact layer 11. Specifically, ammonium gas and TMG as are supplied to the processing chamber with carrier gas to epitaxially grow each barrier layer 22 composed of the non-doped GaN layer. Moreover, with the substrate 2 maintained at the same temperature, ammonium gas, TMG gas, trimethylndium (hereinafter, TMI) gas, and silane gas are supplied with carrier gas to epitaxially grow each well layer 21 composed of the n-type InGaN layer doped with silicon. The barrier layers 22 and well layers 21 are alternately epitaxially grown for a desired number of times by the aforementioned method to form the active layer 12.

Next, after the temperature of the substrate 2 is raised to about 1000° C. to 1100° C., ammonium gas, TMG gas, trimethylaluminum (hereinafter, TMA) gas, and biscyclopentadienylmagnesium (hereinafter, Cp₂Mg) gas are supplied to the processing chamber with carrier gas to epitaxially grow the p-type electron blocking layer 13 composed of the p-type AlGaN layer doped with magnesium on the active layer 12.

Next, with the temperature of the substrate 2 being maintained at about 1000° C. to 1100° C., ammonium gas, TMG gas, and Cp₂Mg gas are supplied to the processing chamber with carrier gas to epitaxially grow the p-type contact layer 14 composed of the p-type GaN layer doped with magnesium on the p-type electron blocking layer 13, thus completing the semiconductor stack 3 in which each of the main surface 12a of the active layer 12 and main surfaces of the layers 11, 13, and 14 is composed of non-polar m-plane.

Next, the anode electrode 5 composed of ZnO is formed on the entire upper surface 14a of the contact layer 14 by spattering or vacuum evaporation.

Next, a resist film (not shown) with a desired pattern is formed on the rear surface 2b of the substrate 2. On the rear surface 2b of the substrate 2 with the resist film formed thereon, Ti and Al layers are formed by resistance heating or vacuum evaporation such as electron beam evaporation. Thereafter, part of the Ti and Al layers on the resist film is removed to form the cathode electrode 4.

Eventually, the obtained product is divided into each device unit to complete the semiconductor light emitting device 1. The anode electrode 5 is then electrically connected to a line on the printed circuit board 101, and the cathode electrode 4 is bonded to a line on the printed circuit board 101 through the wire 102.

In the semiconductor light emitting device 1 according to the first embodiment, as described above, since the main surface 12a of the active layer 12 is composed of nonpolar m-plane, the light emitted at the active layer 12 is polarized. Accordingly, the polarization ratio of light projected to the outside can be increased. Moreover, the polarized light travels in a direction perpendicular to the polarization direction. Accordingly, light traveling in the m-axis direction is several times to about ten times more than light traveling in the a-axis direction. The light extraction efficiency of the semiconductor light emitting device 1, whose light extraction surface (the rear surface 2b) is composed of m-plane, can be therefore increased.

Moreover, in the case where light is transmitted through electrodes which are made thin enough to transmit light and then extracted to the outside, a certain amount of light is absorbed by the electrodes, and light is dispersed at the interface between each electrode and the substrates to reduce the polarization ratio. On the other hand, in the semiconductor light emitting device 1, light is extracted through the area of the rear surface 1b of the substrate 2 where the cathode electrode 4 is not formed. Accordingly, the absorption of light by the electrodes 4 and 5 can be suppressed, thus increasing the light extraction efficiency. Moreover, the reduction of the polarization ratio at the interface between the cathode electrode 4 and substrate 2 is suppressed, thus allowing extraction of light with a high polarization ratio.

Moreover, in the semiconductor light emitting device 1, light is extracted from the rear surface 2b side of the substrate 2 which is much thicker than the semiconductor stack 3. Accordingly, the distance between the active layer 12 and the light extraction surface (rear surface 2b) can be made large, and this can provide the following two effects. As the first effect, the incident angle of the light emitted from the active layer 12 into the rear surface 2b can be made small, so that it is possible to reduce light loss by reflection due to total reflection on the rear surface 2b. As a second effect, the distance between the active layer 12 and the cathode electrode 4 formed on the rear surface 2b can be made large. It is therefore possible to reduce the proportion of light blocked by the cathode electrode 4, thus increasing the light extraction efficiency.

Moreover, in the semiconductor light emitting device 1, mirror finishing of the rear surface 2b of the substrate 2 can prevent dispersion of polarized light on the rear surface 2b. The reduction of the polarization ratio of light projected from the rear surface 2b to the outside can be therefore further suppressed, thus allowing extraction of light with a high polarization ratio.

Moreover, in the semiconductor light emitting device 1, the cathode electrode 4 and anode electrode 5 are formed on both sides of the semiconductor stack 3. Accordingly, only the cathode electrode 4 should be bonded by the wire 102 while the anode electrode 5 is directly connected to the line of the printed circuit board 101 without a wire. It is therefore possible to reduce one of wire bonding steps, thus facilitating the manufacturing process.

Moreover, since the main surface 2a of the substrate 2 is composed of nonpolar m-plane, it is possible to suppress polarization in the growth surface of the semiconductor stack 3 during the growth. The layers 11 to 14 constituting the semiconductor stack 3 can be grown with the growth surface being stabilized, thus improving the crystallinity of the semiconductor stack 3. The light emission efficiency of the active layer 12 can be therefore increased, and the polarization ratio of light can be increased.

Moreover, since the substrate 2 is composed of conductive GaN, it is possible to form the semiconductor stack 3 including few stacking faults and having high crystallinity. The light emission efficiency can be therefore increased.

Moreover, since the cathode electrode 4 is formed in the central part of the rear surface 2b of the substrate, it is possible to suppress unevenness of electrons injected into the active layer 12. Furthermore, since the anode electrode 5 is formed on the entire surface of the upper surface 14a of the p-type contact layer 14, holes can be injected from the anode electrode 5 to the entire area in the horizontal direction, and light can be therefore emitted from the entire area of the active layer 12.

### Second Embodiment

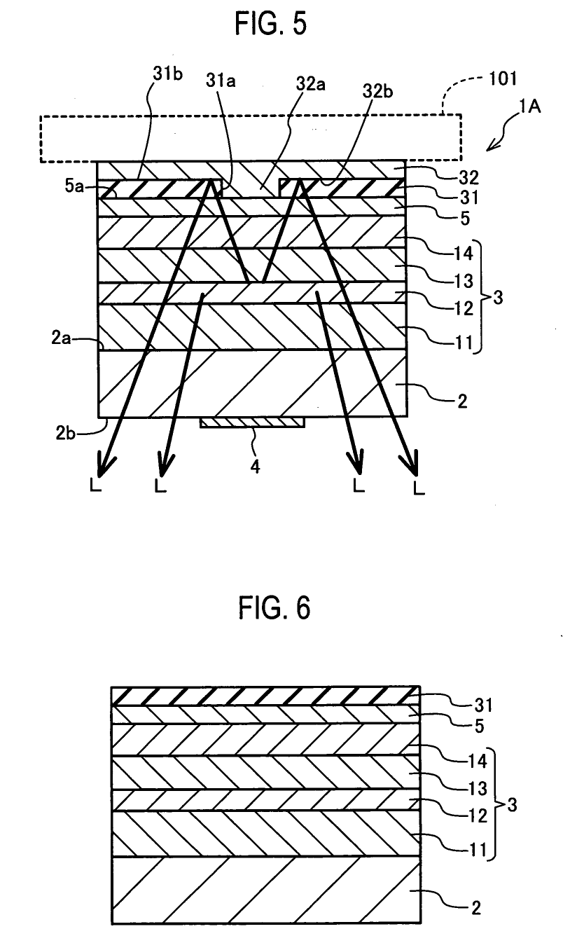

Next, with reference to the drawings, a description is given of a semiconductor light emitting device of a second embodiment which is obtained by modifying a part of the aforementioned first embodiment. FIG. 5 is a cross-sectional view of a semiconductor light emitting element according to the second embodiment. Same components as those of the first embodiment are given same reference numerals, and the description thereof is omitted.

As shown in FIG. 5, a semiconductor light emitting device 1A includes the substrate 2, the semiconductor stack 3, the cathode electrode 4, the anode electrode 5, an insulating film 31, and an external electrode (corresponding to a third electrode of claims) 32. The insulating film 31 and external electrode 32 are sequentially stacked on the upper surface 5a of the anode electrode 5 opposite to the semiconductor stack 3.

The insulating film 31 is to insulate a bottom surface 32b of the external electrode 32 which reflects light. The insulating film 31 is composed of insulating SiO₂ which is capable of transmitting light. The thickness of the insulating film 31 is not more than wavelength of light emitted from the active layer 12 or preferably not more than “wavelength/refraction index of the insulating film 31”. An example of the thickness of the insulating film 31 is about 50 nm. In the central part of the insulating film 31 including the center, an opening 31a is formed for exposing part of the upper surface 5a of the anode electrode 5 and connecting the anode electrode 5 and external electrode 32 to each other.

The external electrode 32 electrically connects the printed circuit board 101 and anode electrode 5 and reflects light traveling in a direction of the printed circuit board 101 to the cathode electrode 4. The external electrode 32 is formed on the upper surface 31b of the insulating film 31. The external electrode 32 is composed of a conductive material capable of reflecting light. Specifically, the external electrode 32 includes an Al layer (about 100 nm thick), a Ti layer (about 10 nm thick), and an Au layer (about 200 nm thick) which are sequentially stacked from the insulating film 31 side. The external electrode 32 may include Ag instead of Al. Moreover, the external electrode 32 includes a protrusion 32a formed in the opening 31a of the insulating film 31. Herein, the thickness of the protrusion 32a is substantially the same as the thickness of the insulating film 31, which is not more than the wavelength of the active layer 12. Accordingly, the reduction of the polarization ratio of light from the active layer 12 due to the protrusion 32a is suppressed similar to the mirror-finished surface. The protrusion 32a of the external electrode 32 is ohmically connected to the anode electrode 5. On the other hand, the bottom surface 32b of the external electrode 32 other than the protrusion 32a is insulated by the insulating film 31 and therefore can reflect light.

Next, a description is given of an operation of the aforementioned semiconductor light emitting device 1A. Description about same operations as those of the semiconductor light emitting device 1 of the first embodiment is simplified.

When forward voltage is applied to the semiconductor light emitting device 1A, the polarized light L is emitted at the active layer 12. The light L traveling towards the substrate 2 among the emitted light L is projected to the outside through the rear surface 2b of the substrate 2. On the other hand, the light L traveling towards the anode electrode 5 among the emitted light L is transmitted through the anode electrode 5 and insulating film 31 to reach the external electrode 32. The light L is reflected on the bottom surface 32b of the external electrode 32 to the substrate 2. The reflected light L is projected to the outside through the rear surface 2b of the substrate 2.

Next, a description is given of a method for manufacturing the aforementioned semiconductor light emitting device 1A with reference to the drawings. FIGS. 6 to 8 are cross-sectional views of the semiconductor light emitting device according to the second embodiment at individual manufacturing steps.

As shown in FIG. 6, the semiconductor stack 3 and anode electrode 5 are formed on the substrate 2 in a similar way to the semiconductor light emitting device 1 of the first embodiment. Thereafter, the insulating film 31 composed of SiO₂ is formed on the anode electrode 5 by plasma CVD.

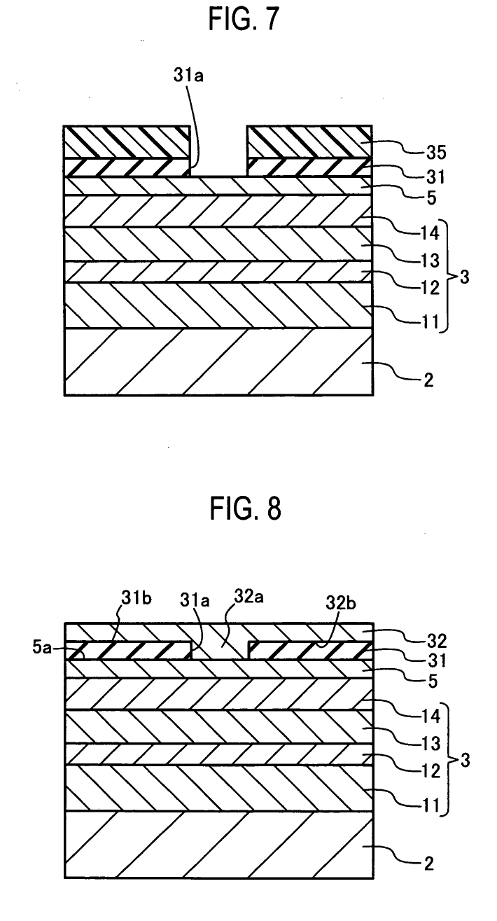

Next, as shown in FIG. 7, a resist film 35 is formed to form the opening 31a in the insulating film 31. The insulating film 31 is then etched to form the opening 31a in the insulating film 31 and expose a part of the anode electrode 5.

Next, as shown in FIG. 8, the external electrode 32 composed of aluminum is formed in the opening 31a and on the upper surface 31b of the insulating film 31 by resistance heating or vacuum evaporation such as electron beam evaporation. Next, as shown in FIG. 5, after the cathode electrode 4 is formed, the obtained product is divided into each device unit, thus completing the semiconductor light emitting device 1A.

The semiconductor light emitting device 1A includes the same structure as that of the semiconductor light emitting device 1 as described above and therefore can provide the same effects as those of the semiconductor light emitting device 1.

Furthermore, the light emitting device 1A includes the external electrode 32 reflecting light traveling in a direction opposite to the substrate 2 back to the substrate 2, so that it is possible to extract more light through the rear surface 2b of the substrate 2. Moreover, the reflection surface (bottom surface 32b) of the external electrode 32 is insulated by the insulating film 31, so that the absorption of light can be prevented.

### Third Embodiment

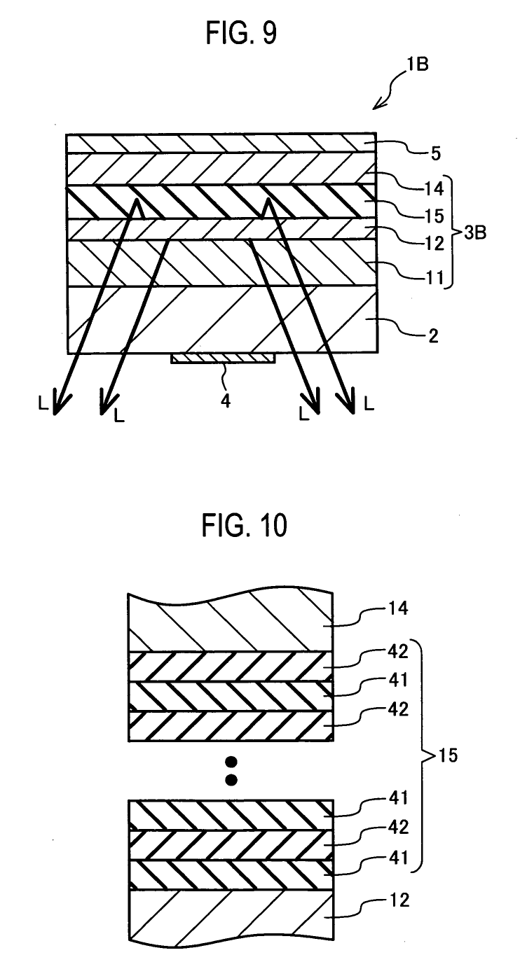

Next, a description is given of a semiconductor light emitting device of a third embodiment obtained by modifying a part of the aforementioned first embodiment with reference to the drawings. FIG. 9 is a cross-sectional view of the semiconductor light emitting device according to the third embodiment. FIG. 10 is a cross-sectional view of a reflection layer. The same components as those of the first embodiment are given the same reference numerals, and the description thereof is omitted.

As shown in FIG. 9, the semiconductor light emitting device 1B according to the third embodiment includes the substrate 2, a semiconductor stack 3B, the cathode electrode 4, and the anode electrode 5.

The semiconductor stack 3B includes the n-type contact layer 11, the active layer 12, a reflection layer 15, and the p-type contact layer 14 which are sequentially stacked from the substrate 2.

The reflection layer 15 reflects light traveling in a direction of the anode electrode 5 back to the substrate 2. As shown in FIG. 10, the reflection layer 15 has a DBR (distributed Bragg reflection) structure including p-type Al_{y}Ga_{1-y}N layers 41 and p-type GaN layers 42 alternately and cyclically stacked.

Herein, the value “Y”, which is a proportion of Al in each p-type Al_{y}Ga_{1-y}N layer 41, is not particularly limited. In order to obtain a large difference in refraction index between the p-type Al_{y}Ga_{1-y}N layers 41 and p-type GaN layers 42, preferably Y>=0.2 and more preferably, Y=1.0. The p-type Al_{y}Ga_{1-y}N layers 41 and p-type GaN layers 42 are doped with magnesium as p-type dopants. In the following description, the p-type Al_{y}Ga_{1-y}N layers 41 are referred to as the p-type AlGaN layers 41.

Thickness d of a pair of the p-type AlGaN layers 41 and p-type GaN layers 42 constituting the reflection layer 15 is set as follows;

d=(λ/4n₁)+(λ/4n₂) (1)

so that the reflected light rays are strengthened. Herein, λ is wavelength of light emitted at the active layer 12, and n₁ and n₂ are refraction indices of the p-type AlGaN layers 41 and p-type GaN layers 42, respectively. When λ=430 nm, n₁=2.38, and n₂=2.52 in the above equation (1), the thickness d of a pair of the p-type AlGaN layers 41 and p-type GaN layers 42 is about 88 nm. The number of pairs of the p-type AlGaN and p-type GaN layers 41 and 42 is not particularly limited but is preferably not less than 10 pairs for the purpose of increasing the degree of reflection.

Next, a description is given of an operation of the semiconductor light emitting device 1B. In the semiconductor light emitting device 1B, upon application of forward voltage, polarized light L is emitted at the active layer 12. Among the emitted light L, the light L traveling in the direction of the substrate 2 is projected to the outside through the rear surface 2b of the substrate 2. On the other hand, among the emitted light L, the light L traveling in the direction of the anode electrode 5 is reflected on the reflection layer 15 to the substrate 2. The reflected light L is projected to the outside through the rear surface 2b of the substrate 2.

Next, a description is given of a method for manufacturing the reflection layer 15. Each p-type AlGaN layer 41 constituting the reflection layer 15 is formed by supplying ammonium gas, TMA gas, TMG gas, and CP₂Mg gas with carrier gas with the temperature of the substrate 2 set to about 1050° C. to 1150° C. Each p-type GaN layer 42 constituting reflection layer 15 are formed by supplying ammonium gas, TMG gas, and Cp₂Mg gas with carrier gas with the temperature of the substrate 2 being set to 1050 to 1150° C. These steps are alternately performed for a desired number of times to form the reflection layer 15. The other steps are the same as those of the first embodiment, and the description thereof is omitted.

The semiconductor light emitting device 1B according to the third embodiment has a substantially same structure as that of the semiconductor light emitting device 1 according to the first embodiment and provides the same effects.

Moreover, the semiconductor light emitting device 1B according to the third embodiment includes the reflection layer 15, which is capable of reflecting light traveling in the direction of the anode electrode 5 to the substrate 2, thus increasing the light extraction efficiency. Moreover, the reflection layer 15 is formed within the semiconductor stack 3, so that the semiconductor light emitting device 1B can be miniaturized.

Hereinabove, the present invention is described in detail using the embodiments but is not limited to the embodiments described in the specification. The scope of the present invention is determined by the description of claims and equivalents thereof. A description is given of a modification obtained by partially changing the aforementioned embodiments.

For example, each of the main surface of the substrate and the main surface of each layer constituting the semiconductor stack, including the active layer, is composed of nonpolar m-plane but may be composed of a substantially nonpolar plane or substantially semipolar plane other than m-plane. Herein, the substantially nonpolar plane is a nonpolar plane and a plane with an off angle of ±1° or less from a nonpolar plane. The above substantially semipolar plane is a semipolar plane and a plane with an off angle of ±1° or less from a semipolar plane and except for a polar plane.

Moreover, semiconductor materials constituting the semiconductor stack, thickness of each layer, and the like can be properly changed.

Moreover, the anode electrode may be composed of ZnO, ITO, SnO₂, or the like. The anode electrode may be composed of Ni/Au, palladium/Au, or the like sequentially from the p-type contact layer. Furthermore, the cathode electrode may be composed of Al, ZnO, ITO, ZnO, or the like. Especially making the cathode electrode of a transparent electrode can increase the light extraction efficiency.

Moreover, in each aforementioned embodiment, the active layer is configured to be capable of emitting blue light. However, the active layer may be configured to emit light with different wavelength (for example, about 485 nm to 530 nm) by changing the proportion of In in the InGaN of the well layer.

What is claimed is:

1. A semiconductor light emitting device comprising:
a substrate;
a semiconductor stack formed on one of surfaces of the substrate and including an active layer composed of a group III nitride semiconductor having a main surface which is a substantially nonpolar plane or substantially semipolar plane;
a first electrode formed in a part of a first electrode surface which is the other surface of the substrate; and
a second electrode formed on a second electrode surface opposite to the first electrode surface across the substrate and semiconductor stack.

2. The device of claim 1, wherein a plane area of the first electrode is not more than 50% of a plane area of the first electrode surface.

3. The device of claim 1, wherein the main surface is composed of m-plane.

4. The device of claim 1, wherein the substrate is composed of conductive GaN.

5. The device of claim 1, wherein the first electrode is formed in a central part of the first electrode surface.

6. The device of claim 1, wherein the second electrode is formed on the entire second electrode surface.

7. The device of claim 1, wherein the first electrode surface is mirror-finished.

8. The device of claim 1, wherein an insulating film and a third electrode are sequentially stacked on a surface of the second electrode opposite to the semiconductor stack, and
the third electrode is electrically connected to a part of the second electrode and reflects light.

9. The device of claim 8, wherein the insulating film includes an opening to expose a part of the second electrode, and
the third electrode is electrically connected to the second electrode through a projection formed in the opening of the insulating film.

10. The device of claim 8, wherein thickness of the insulating film is not more than wavelength of light from the active layer.

11. The device of claim 8, wherein the second electrode is composed of metal oxide transmitting light, and
the third electrode is composed of metal.

12. The device of claim 8, wherein the third electrode is insulated from the second electrode except the opening of the insulating film.

13. The device of claim 1, wherein the semiconductor stack includes a reflection layer formed at a position opposite to the substrate across the active layer.

14. The device of claim 13, wherein the reflection layer includes two types of semiconductor materials having different refraction indices and stacked cyclically.

15. The device of claim 14, wherein the reflection layer has a DBR (distributed Bragg reflection) structure.
